(19) United States
(12) Patent Application Publication
(10) Pub. No.: US 2026/0129935 A1
(43) Pub. Date: May 7, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Guan-Lin CHEN, Hsinchu (TW); Huan-Chieh SU, Hsinchu (TW); Kuo-Cheng CHIANG, Hsinchu (TW); Shi Ning JU, Hsinchu (TW); CHIH-HAO WANG, Hsinchu (TW)

(73) Assignee: Taiwan Semiconductor Manufacturing Company, Ltd., Hsinchu (TW)

(21) Appl. No.: 18/934,409

(22) Filed: Nov. 1, 2024

(51) Int. Cl. H01L 29/66; H01L 21/8234; H01L 27/088; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 64/021; H10D 84/0128; H10D 84/0147; H10D 84/038; H10D 84/83

(57) ABSTRACT

A method for manufacturing a semiconductor device is provided, including the following steps. A first protective layer and a second protective layer are formed on top of a stack of a plurality of first semiconductor layers and a plurality of second semiconductor layers alternately disposed. The second semiconductor layers are removed to form at least one cavity between the first semiconductor layers. A sacrificial dielectric layer and a plurality of dielectric spacers are formed between the first semiconductor layers. The sacrificial dielectric layer located under the second protective layer is removed to form a first cavity. The sacrificial dielectric layer between the first semiconductor layers is removed to form a second cavity. The second protective layer exposed in the first cavity is removed so that the height of the first cavity is greater than the height of the second cavity.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-16 illustrate perspective views of various stages for manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure can pattern a gate all around (GAA) transistor structure by any suitable method. For example, one or more photolithography processes may be used to pattern the structure, including dual patterning processes or multiple patterning processes. Typically, a dual or multi-patterning process combines a photolithography process with a self-aligned process, allowing the creation of patterns with, for example, smaller pitches than achievable using a single direct photolithography process. For example, in one embodiment, a sacrificial dielectric layer is formed over a substrate and patterned using a photolithography process. Spacers are formed along the patterned sacrificial dielectric layer using a self-aligned process. The sacrificial dielectric layer is then removed, and the remaining spacers can then be used to pattern the GAA structure.

The present disclosure relates to semiconductor devices and methods of manufacturing the same. More specifically, some embodiments of the present disclosure relate to semiconductor devices including improved gate protect top (GPT) layer to create a large space for gate filling metal (such as TiN). The semiconductor devices proposed herein include p-type semiconductor devices or n-type semiconductor devices. Additionally, a semiconductor device may have one or more channel regions (e.g., nanowires) associated with a single continuous gate structure, or multiple gate structures. A person having ordinary skills may recognize other examples of semiconductor devices that may benefit from aspects of the present disclosure.

While the embodiments of this disclosure are discussed with respect to nanostructure channel FETs (e.g., Horizontal Gate All Around (HGAA) FETs, Vertical Gate All Around (VGAA) FETs, nanosheet/nanowire FET, nano-ribbon FET, Multi-Bridge-Channel FET), implementations of some aspects of the present disclosure may be used in other processes and/or in other devices, such as planar FETs, Fin-FETs, and other suitable devices. A person having ordinary skills in the art will readily understand other modifications that may be made are contemplated within the scope of this disclosure.

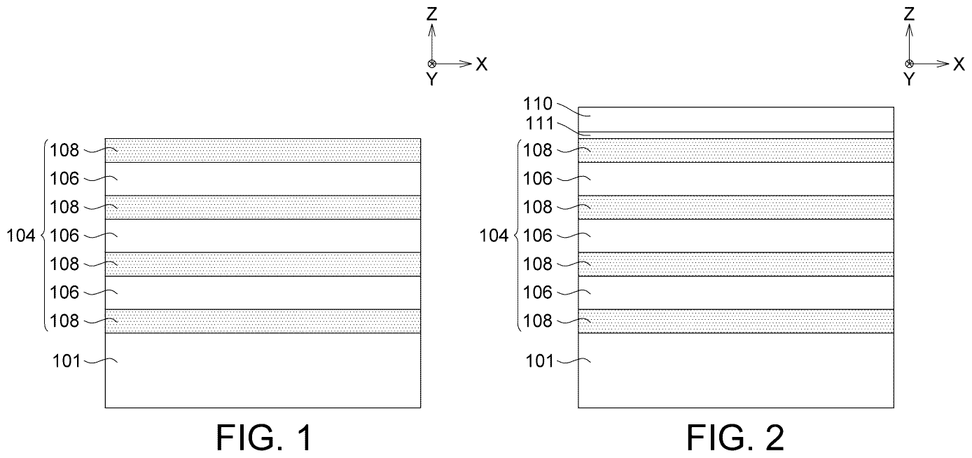

FIGS. 1-16 are perspective views of various stages for manufacturing a semiconductor device 100 according to embodiments of the present disclosure. It will be appreciated that for additional embodiments of the method, additional steps may be provided before, during, and after the processes illustrated in FIGS. 1-16, and some of the steps described below may be replaced or eliminated. The sequence of steps/processes is unrestricted and interchangeable.

As shown in FIG. 1, the semiconductor device 100 includes a stack of semiconductor layers 104 formed over a substrate 101. The substrate 101 may be a semiconductor substrate. The substrate 101 may include single crystal semiconductor materials such as, but not limited to, silicon (Si), germanium (Ge), silicon germanium (SiGe), gallium arsenide (GaAs), indium antimonide (InSb), gallium phosphide (GaP), Gallium antimonide (GaSb), indium aluminum arsenide (InAlAs), indium gallium arsenide (InGaAs), gallium antimony phosphide (GaSbP), gallium arsenide antimonide (GaAsSb) and indium phosphide (InP). In some embodiments, the substrate 101 is a silicon-on-insulator (SOI) substrate having an insulating layer (not shown) disposed between two silicon layers for reinforcement. In one aspect, the insulating layer is an oxygen-containing layer.

The stack of semiconductor layers 104 includes semiconductor layers made of different materials to facilitate the formation of nanostructured channels in multi-gate devices such as nanostructured field effect transistors. In some embodiments, the stack of semiconductor layers 104 includes a plurality of first semiconductor layers 106 and a plurality of second semiconductor layers 108 (also referred to as dummy layers). In some embodiments, the stack of semiconductor layers 104 includes alternating first semiconductor layers 106 and second semiconductor layers 108, and the first semiconductor layers 106 and the second semiconductor layers 108 are disposed parallel to each other. The first semiconductor layer 106 and the second semiconductor layer 108 are made of semiconductor materials with different etching selectivities and/or different oxidation rates. For example, the first semiconductor layer 106 can be made of Si, and the second semiconductor layer 108 can be made of SiGe. In some examples, first semiconductor layer 106 may be made of germanium-doped silicon, and second semiconductor layer 108 may be made of SiGe. In some examples, first semiconductor layer 106 can be made of SiGe and second semiconductor layer 108 can be made of Si. In some embodiments, the first semiconductor layer 106 can be made of SiGe having a first germanium concentration range, and the second semiconductor layer 108 can be made of SiGe having a second germanium concentration range that is lower or greater than the first germanium concentration range. Alternatively, in some embodiments, any one of the first semiconductor layer 106 and the second semiconductor layer 108 may be or include other materials, such as Ge, SiC, GeAs, GaP, InP, InAs, InSb, GaAsP, AlInAs, AlGaAs, InGaAs, GaInP, GaInAsP or any combination thereof. In some embodiments, the second semiconductor layers 108 may be crystal-oxide, such as HfO₂, ZrO₂, ZnO₂, MgO, IGZO, Y₂O₃ and beta-SiN.

The thickness of the first semiconductor layer 106 and the second semiconductor layer 108 may vary depending on application and/or device performance considerations. In some embodiments, each of the first semiconductor layer 106 and the second semiconductor layer 108 has a thickness between about 5 nm and about 30 nm. In other embodiments, each of the first semiconductor layer 106 and the second semiconductor layer 108 has a thickness between about 10 nm and about 20 nm. In some embodiments, each of the first semiconductor layer 106 and the second semiconductor layer 108 has a thickness between about 6 nm and about 12 nm. Each second semiconductor layer 108 may have a thickness equal to, smaller than, or larger than that of the first semiconductor layer 106. The second semiconductor layer 108 may eventually be removed and used to define the vertical distance between adjacent channels of the semiconductor device structure 100.

The first semiconductor layers 106 or a portion thereof may form the nanostructured channels of the semiconductor device 100 in a later manufacturing stage. The term “nanostructure” is used herein to mean any portion of a material that has a nanometer or even micron dimension and has an elongated shape, regardless of the cross-sectional shape of the portion. Accordingly, this term refers to elongated material portions and bundled or rod-like material portions of circular and substantially circular cross-sections, including, for example, cylindrical or substantially rectangular cross-sections. The nanostructure channels of the semiconductor device 100 may be surrounded by gate electrodes. The semiconductor device 100 may include nanostructured transistors. Nanostructured transistors can be called nanowire transistors, gate-all-around transistors, multi-bridge channel (MBC) transistors, or any transistor with a gate electrode surrounding a channel. The use of first semiconductor layers 106 to define one or more channels of semiconductor device 100 is discussed further below.

The first semiconductor layer 106 and the second semiconductor layer 108 are formed by any suitable deposition process, such as an epitaxial process. For example, the stack of semiconductor layers 104 may be epitaxially grown by a molecular beam epitaxy (MBE) process, a metalorganic chemical vapor deposition (MOCVD) process, and/or other suitable crystal growth process. Although the three first semiconductor layers 106 and the four second semiconductor layers 108 are alternately stacked as shown in FIG. 1, it should be understood that according to the predetermined number of nanostructure channels of each field effect transistor, A stack of semiconductor layers 104 can be any number of first semiconductor layers 106 and second semiconductor layers 108. For example, the number of first semiconductor layers 106 (i.e., the number of channels) may be between 2 and 8.

In some embodiments, a hard mask layer (not shown) formed on the stack of semiconductor layers 104 is patterned using multiple patterning steps including photolithography and etching processes. The etching process may include dry etching, wet etching, reactive ion etching (RIE) and/or other suitable processes. The photolithography process may include forming a photoresist layer (not shown) over the hard mask layer, exposing the photoresist layer to the pattern, performing a post-exposure bake process, and developing the photoresist layer to form a masking element of the photoresist layer. In some embodiments, an electron beam (e-beam) lithography process may be used to pattern the photoresist layer to form the masking element. The etching process creates trenches in the unprotected areas through the hard mask layer, through the stack of semiconductor layers 104 and into the substrate 101, leaving a plurality of vertically extending fin structures 112. The trench extends along the X direction. The trenches may be etched using dry etching (e.g., RIE), wet etching, and/or combinations thereof.

In FIG. 2, a first protective layer 110 and a second protective layer 111 are formed above the stack of semiconductor layers 104. The first protective layer 110 and the second protective layer 111 may be made of dielectric materials, such as silicon nitride (SiN), silicon oxynitride (SiON), silicon nitride carbide (SiCN), silicon oxycarbide (SiCO), silicon oxycarbonitride (SiOCN) and/or combinations thereof. In some embodiments, the dielectric constant of the first protective layer 110 and the second protective layer 111 may range from about 3.5 to 5.5, and may be formed by atomic layer deposition, pulsed plasma chemical vapor deposition, or any suitable deposition process. The first protective layer 110 covers the second protective layer 111, and the thickness of the first protective layer 110 may be greater than that of the second protective layer 111. In some embodiments, the thickness of the second protective layer 111 may be about 0.1 nm to 5 nm, and the carbon content in the second protective layer 111 is lower than the carbon content in the first protective layer 110, for example, the carbon content in the second protective layer 111 can range from 0 to 6 atomic percent.

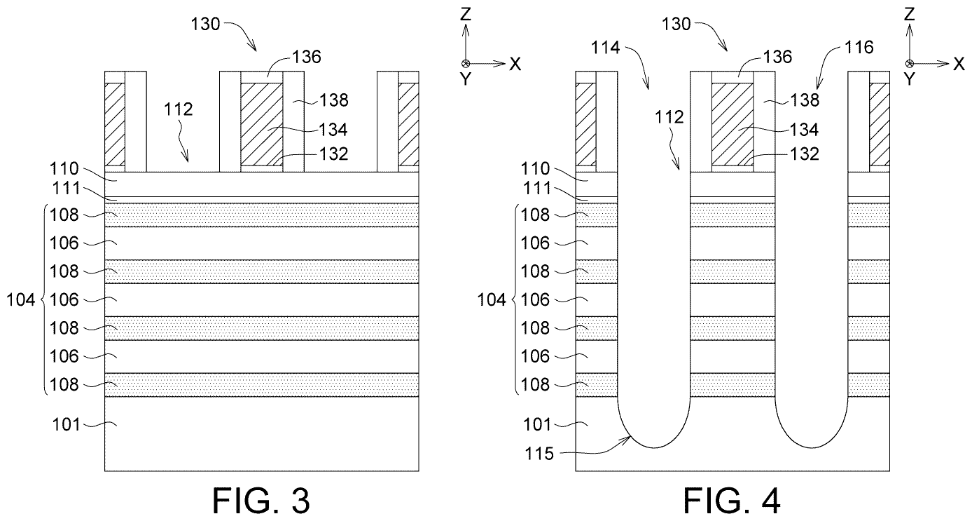

In FIG. 3, one or more sacrificial gate structures 130 are formed above the first protective layer 110 and the second protective layer 111. The sacrificial gate structure 130 may be formed over a portion of the fin structure 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 can be formed by sequentially depositing a blanket layer of the sacrificial gate dielectric layer 132, the sacrificial gate electrode layer 134, and the mask layer 136, and then these layers are patterned into a sacrificial gate structure 130. The gate spacers 138 are then formed on the sidewalls of the sacrificial gate structure 130. For example, the gate spacers 138 may be formed by conformally depositing one or more layers of gate spacers 138 and anisotropically etching the one or more layers. Although one sacrificial gate structure 130 is shown in the figures, in some embodiments, two or more sacrificial gate structures 130 may be configured along the X direction.

The sacrificial gate dielectric layer 132 may include one or more layers of dielectric material, such as a silicon oxide-based material. The sacrificial gate electrode layer 134 may include silicon, such as polycrystalline silicon or amorphous silicon. The mask layer 136 may include more than one layer, such as an oxide layer and a nitride layer. The gate spacer 138 may be made of a dielectric material, such as silicon oxide, silicon nitride, silicon carbide, silicon oxynitride (SiON), silicon nitride carbide (SiCN), silicon oxycarbide (SiCO), silicon oxycarbonitride (SiOCN) and/or combinations thereof.

In FIG. 4, by removing the portion of the fin structure 112 that is not covered by the sacrificial gate structure 130, the two opposite sides of the first semiconductor layer 106 and the second semiconductor layer 108 are exposed. The first semiconductor layer 106 covered by the sacrificial gate electrode layer 134 of the sacrificial gate structure 130 serves as a channel region of the semiconductor device 100. Trenches that are exposed to opposite sides of the sacrificial gate structure 130 define source/drain (S/D) regions 114 and 116 of the semiconductor device 100. In some cases, some source/drain regions 114 and 116 may be shared between various transistors. For example, each of the source/drain regions 114 and 116 may be connected together and implemented as a multifunctional transistor. The trenches can be completed by an etching process, which can be dry etching or wet etching such as RIE, NBE or the like, such as using tetramethylammonium hydroxide (TMAH), ammonium hydroxide (NH₄OH) or any suitable etchant.

In FIG. 4, the trench depth of the source/drain regions 114 and 116 can be controlled by the etching process. In one embodiment, the bottom 115 of the trench is, for example, slightly lower than the upper surface 101a of the substrate 101 or coplanar with the upper surface 101a of the substrate 101. The etchant can reach the substrate 101 through the trench to expose the upper surface 101a of the substrate 101.

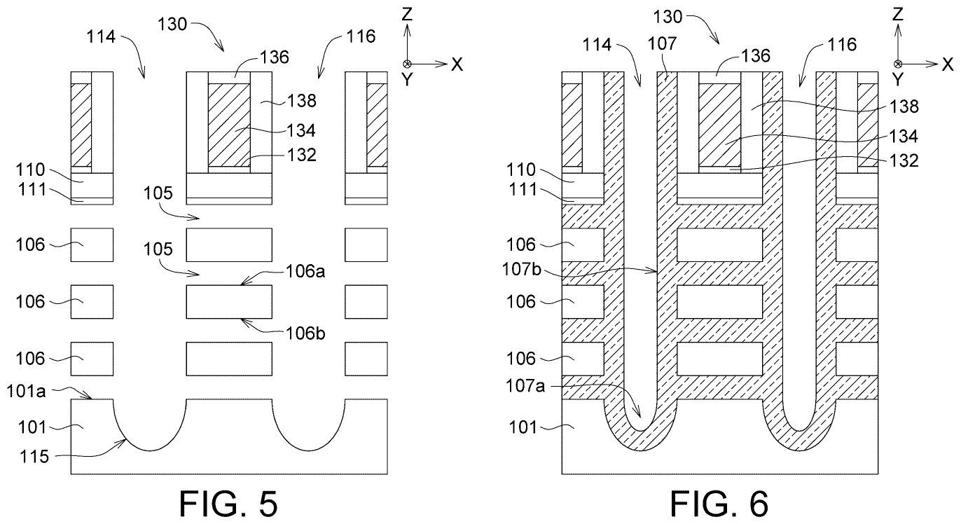

Referring to FIG. 5, each second semiconductor layer 108 of the stack of semiconductor layers 104 is removed to form a cavity 105. In some embodiments, the second semiconductor layer 108 is removed through a wet etching process. In the case where the second semiconductor layer 108 is made of SiGe and the first semiconductor layer 106 is made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP) or potassium hydroxide (KOH) solutions to expose the upper and lower surfaces 106a and 106b of the first semiconductor layers 106 and the top surface 101a of the substrate 101.

In FIG. 6, after the second semiconductor layer 108 is removed, a dielectric material is deposited on the upper and lower surfaces of the first semiconductor layers 106, a lower surface of the second protective layer 111 and the upper surface 101a of the substrate 101 exposed in the cavity 105 to form a sacrificial dielectric layer 107. The sacrificial dielectric layer 107 may be made of a low-k dielectric material, such as SiOx. In addition, the sacrificial dielectric layer 107 may also cover the side surfaces of the sacrificial gate structure 130 and the side surfaces of each first semiconductor layers 106. The sacrificial dielectric layer 107 covers the upper surface 101a of the substrate 101, and the thickness of the bottom portion 107a of the sacrificial dielectric layer 107 is less than 5 nm to facilitate subsequent complete removal of the bottom portion 107a of the sacrificial dielectric layer 107.

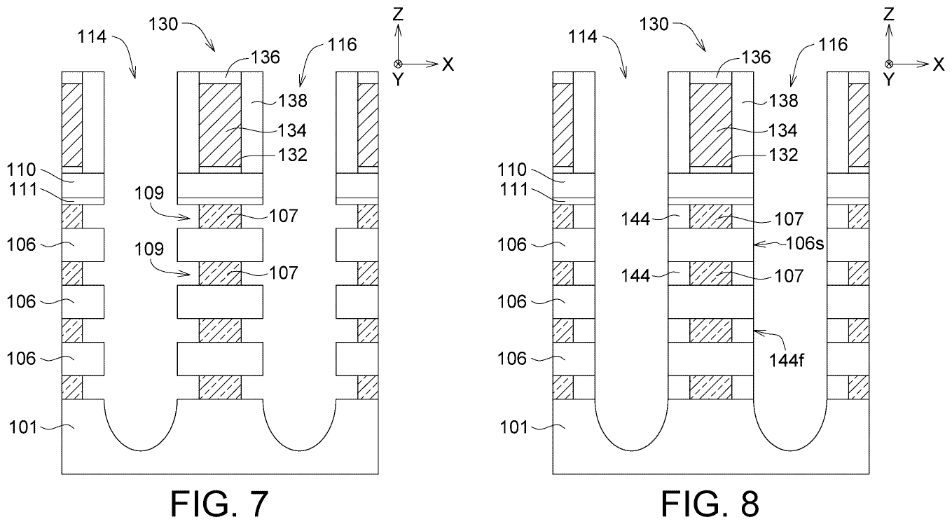

In FIG. 7, selective etching is performed to remove the bottom portion 107a of the sacrificial dielectric layer 107 covering the upper surface 101a of the substrate 101 and remove the edge portions 107b of the sacrificial dielectric layer 107 horizontally along the X direction. In some embodiments, a portion of the sacrificial dielectric layer 107 is removed through a selective wet etching process. By removing the edge portion 107b of the sacrificial dielectric layer 107 along the X direction, the side surfaces 106s and a part of the upper and lower surfaces 106a and 106b of the first semiconductor layer 106 are exposed to form a plurality of cavities 109 between the first semiconductor layers 106 and between the second protective layer 111 and the uppermost first semiconductor layer 106.

In FIG. 8, a dielectric layer is deposited in each cavity 109 to form dielectric spacers 144 (or inner spacers). The dielectric spacer 144 between the second protective layer 111 and the uppermost first semiconductor layer 106 is called a first dielectric spacer, and the dielectric spacers 144 between the first semiconductor layers 106 are called second dielectric spacers. In addition to filling the cavity 109, the dielectric layer is also deposited in the bottom 115 of the trench and the side surfaces of the first semiconductor layer 106. In order to avoid excess dielectric layer remaining in the bottom 115 of the trench, the dielectric layer is partially removed through the etching process, leaving only the dielectric spacers 144 in the cavities 109. The etching process may be dry or wet etching such as RIE, NBE or the like. The dielectric spacers 144 may be made of a low-k dielectric material, such as SiON, SiCN, SiOC, SiOCN, or SiN. In some embodiments, the dielectric spacers 144 are formed from a material having a dielectric constant in the range of 3.5 to 5.5. The dielectric spacers 144 may be formed by atomic layer deposition, pulsed plasma chemical vapor deposition, or any suitable deposition process. The end portion of the dielectric spacers 144 below the first semiconductor layers 106 may have a flat surface 144f that is substantially coplanar with the side surface 106s of the first semiconductor layers 106.

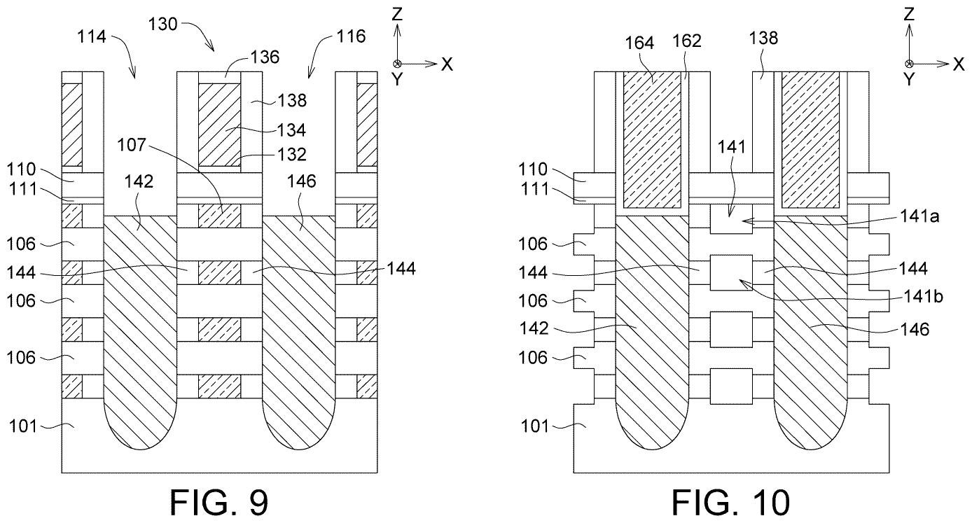

In FIG. 9, a semiconductor material (such as silicon germanium or silicon) can be further deposited or backfilled in the trenches of the source/drain regions 114 and 116 to form epitaxial source/drain features 142 and 146. The epitaxial source/drain features 142 and 146 may be made of one or more layers of Si, SiP, SiC, and SiCP for n-channel FETs, or Si, SiGe, Ge for p-type channel FETs. For p-type channel FETs, p-type dopants such as boron may also be included in the epitaxial source/drain features 142 and 146. The epitaxial source/drain features 142 and 146 may be formed by epitaxial growth methods using chemical vapor deposition, atomic layer deposition, or molecular beam epitaxy. The epitaxial source/drain features 142 and 146 may be grown vertically and horizontally to form facets, which may correspond to crystallographic planes of the material used for the substrate 101. In some cases, the epitaxial source/drain features 142 and 146 may be grown and merged with adjacent epitaxial source/drain features 142 and 146. In some embodiments, prior to forming the epitaxial source/drain features 142 and 146, a source/drain pre-clean process may be performed to remove native oxide layers on the first semiconductor layers 106 and the dielectric spacers 144. The source/drain pre-cleaning process may be an inert gas sputtering process (e.g., argon sputtering) or a plasma-based cleaning process. In one embodiment, the source/drain pre-clean process is a SiCoNi process that uses remote plasma to generate ammonium fluoride (NH₄F) etchant from nitrogen trifluoride (NF₃) and ammonia (NH₃) to minimize damage to the semiconductor device 100.

In one example shown in FIG. 9, one of a pair of epitaxial source/drain features 142 and 146 disposed on one side of the sacrificial gate structure 130 is designated as the source feature (source terminal), and the other of the pair of epitaxial source/drain features 142 and 146 disposed on the other side of the sacrificial gate structure 130 is designated as the drain feature (the drain terminal). The source feature (source terminal) and the drain feature (drain terminal) are connected by a channel layer (e.g., first semiconductor layer 106). The epitaxial source/drain features 142 and 146 are in contact with the first semiconductor layers 106 beneath the sacrificial gate structure 130. In some cases, the epitaxial source/drain features 142 and 146 may grow beyond the topmost semiconductor channel (i.e., the first semiconductor layer 106) to contact the first protective layer 110 and the second protective layer 111.

In some embodiments, in FIG. 10, a contact etch stop layer (CESL) 162 is conformally formed on the exposed surface of the semiconductor device 100. The contact etch stop layer 162 covers the sidewalls of sacrificial gate structure 130 and the upper surfaces of epitaxial source/drain features 142 and 146. The contact etch stop layer 162 may include an oxygen-containing material or a nitrogen-containing material, such as silicon nitride, silicon carbonitride, silicon oxynitride, silicon carbonitride, silicon oxide, silicon oxycarbide, the like, or combinations thereof, and may be formed by CVD, PECVD, ALD or any suitable deposition technique. Next, a first interlayer dielectric (ILD) 164 is formed on the contact etch stop layer 162 of the semiconductor device 100. The material of the first interlayer dielectric layer 164 may include compounds including Si, O, C, and/or H, such as silicon oxide, ethyl orthosilicate oxide, SiCOH, and SiOC. Organic materials such as polymers may also be used for the first interlayer dielectric layer 164. The first interlayer dielectric layer 164 may be deposited by a PECVD process or other suitable deposition techniques. In some embodiments, after forming the first interlayer dielectric layer 164, the semiconductor device 100 may undergo a thermal process to anneal the first interlayer dielectric layer 164.

In FIG. 10, the sacrificial dielectric layer 107 is removed to form a plurality of cavities 141. That is, the sacrificial dielectric layer 107 between the second protective layer 111 and the uppermost first semiconductor layer 106 is removed to form a first cavity 141a, and the sacrificial dielectric layer 107 between the first semiconductor layers 106 is removed to form a second cavity 141b. In some embodiments, the sacrificial dielectric layer 107 is removed through a selective wet etching process. The sacrificial dielectric layer 107 is removed to expose the upper and lower surfaces of the first semiconductor layer 106. In addition, plasma dry etching and/or wet etching may also be used to remove the sacrificial gate structure 130. The sacrificial gate electrode layer 134 may first be removed by any suitable process, such as dry etching, wet etching, or a combination thereof. The sacrificial gate dielectric layer 132 is then removed by performing any suitable process (such as dry etching, wet etching, or a combination thereof). In some embodiments, a wet etchant, such as a tetramethylammonium hydroxide solution, may be used to selectively remove the sacrificial gate electrode layer 134 but not the gate spacer 138, the first interlayer dielectric layer 164 and the contact etch stop layer 162.

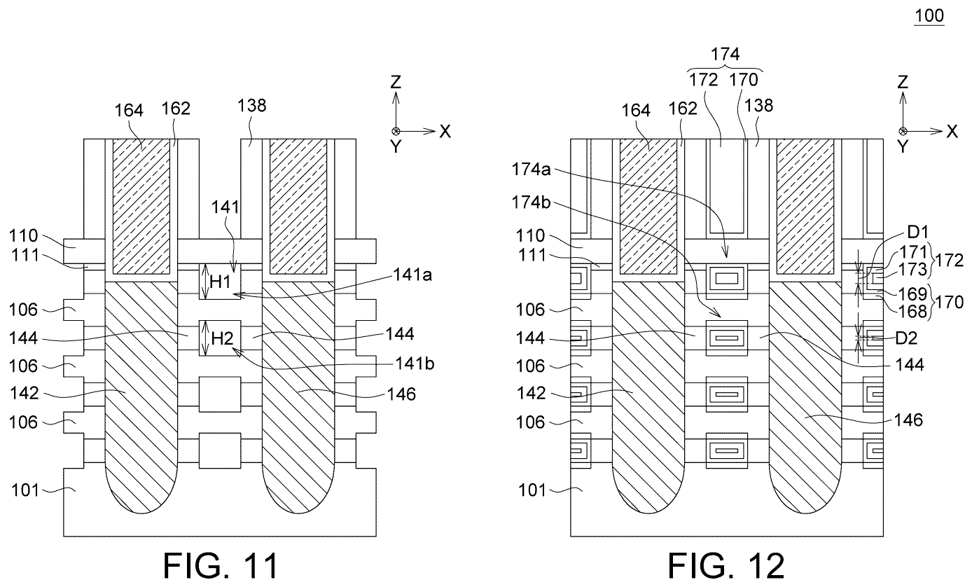

In FIG. 11, after the sacrificial dielectric layer 107 is removed, the second protective layer 111 exposed in the first cavity 141a is further removed, but the first protective layer 110 is not etched due to selective etching. The etching process may be dry etching or wet etching such as RIE, NBE or the like. After the second protective layer 111 is removed, the distance between the first protective layer 110 and the uppermost first semiconductor layer 106 becomes larger (that is, the height H1 of the first cavity 141a in the Z-axis direction is greater than the height H2 of the second cavity 141b), for example, the height H1 increases by 0.1 nm to 5 nm. In subsequent processes, the increased distance (i.e., H1) can help the gate filling metal 173 have more space to fill between the first protective layer 110 and the uppermost first semiconductor layer 106.

In FIG. 12, after the second protective layer 111 is removed, a gate dielectric layer 170 is formed to surround each of the first semiconductor layers 106, and a gate electrode layer 172 is formed on the gate dielectric layer 170. The gate dielectric layer 170 and the gate electrode layer 172 may be collectively referred to as a gate structure 174. The gate structure 174 between the first protective layer 110 and the uppermost first semiconductor layer 106 is called a first gate structure 174a with a first height H1, and the gate structures 174 between the first semiconductor layers 106 are called second gate structures 174b with a second height H2 (i.e., H1>H2). In some embodiments, the gate dielectric layer 170 includes one or more layers of dielectric materials, such as silicon oxide, silicon nitride, high-k dielectric materials, other suitable dielectric materials, and/or combinations thereof. The gate dielectric layer 170 includes an interface layer 168 (e.g., a silicon oxide layer) and a high-k dielectric layer 169 on the interface layer 168. The high-k dielectric layer 169 includes a dielectric material having a high dielectric constant (e.g., greater than the dielectric constant of thermally oxidized silicon (approximately 3.9)).

In some embodiments, the interface layer (IL) 168 is formed between the high-k dielectric layer 169 and the exposed surfaces of the first semiconductor layers 106. In such cases, the interface layer 168 may also be formed on the well portion of the substrate 101. The interface layer 168 may include or be made of oxygen-containing materials or silicon-containing materials, such as silicon oxide, silicon oxynitride, oxynitride, hafnium silicate, and the like. The interface layer 168 and the high-k dielectric layer 169 can be formed by CVD, ALD, cleaning process or any suitable process. Examples of the high-k dielectric layer 169 include HfO₂, HfSiO, HfSiON, HfTaO, HfTiO, HfZrO, zirconium oxide, alumina, titanium oxide, hafnium dioxide-aluminum oxide (HfO₂—Al₂O₃) alloy, and other suitable high-k dielectric materials and/or combinations thereof. The high-k dielectric layer 169 may be formed by CVD, ALD, or any suitable deposition technique.

The gate electrode layer 172 may include one or more layers of conductive materials, such as polycrystalline silicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials and/or any combination thereof. The gate electrode layer 172 may be formed by CVD, ALD, electroplating or other suitable deposition techniques. The gate electrode layer 172 may also be deposited over the upper surface of the first interlayer dielectric layer 164. Next, the gate dielectric layer 170 and the gate electrode layer 172 formed over the first interlayer dielectric layer 164 are removed by using, for example, chemical mechanical polishing until the top surface of the first interlayer dielectric layer 164 is exposed.

In some embodiments, as shown in FIG. 12, the uppermost gate electrode layer 172 (i.e., first gate electrode layer 172) between the first protective layer 110 and the semiconductor layer 106 has a larger thickness D1 relative to the thickness D2 of the gate electrode layer 172 (i.e., second gate electrode layer 172) between the semiconductor layers 106, that is, the thickness D1 is greater than the first thickness D2, it is mainly because the second protection layer 111 is etched to add extra space to form a thicker gate electrode layer 172.

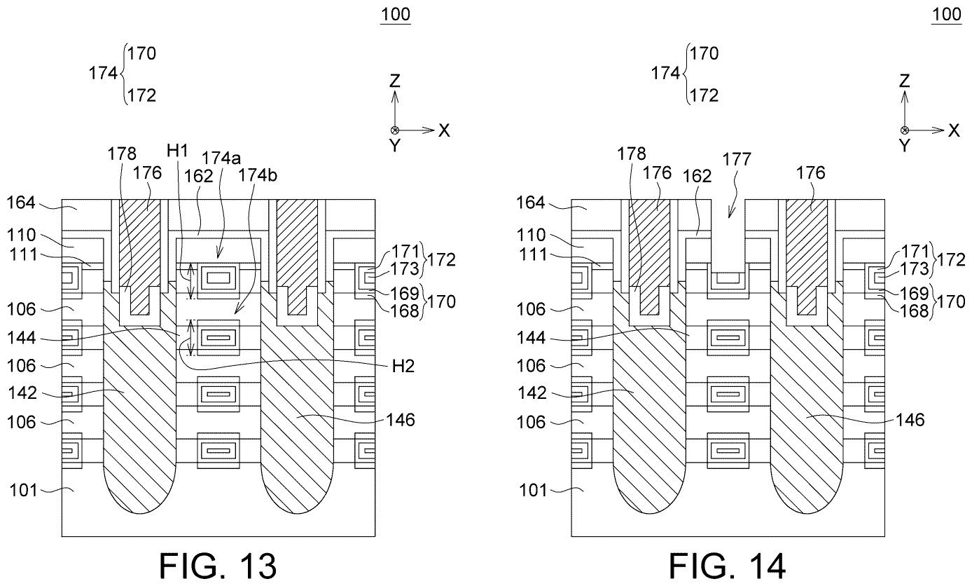

In FIG. 13, source/drain contacts 176 are formed in the first interlayer dielectric layer 164. Prior to forming the source/drain contacts 176, contact openings are formed in the first interlayer dielectric layer 164 to expose the epitaxial source/drain features 142 and 146. The contact openings are formed through various layers, including first interlayer dielectric layer 164 and contact etch stop layer 162, using suitable photolithography and etching techniques to expose epitaxial source/drain features 142 and 146. In some embodiments, upper portions of the epitaxial source/drain features 142 and 146 are etched.

After forming the contact openings, a silicide layer 178 is formed over the epitaxial source/drain features 142 and 146. The silicide layer 178 electrically couples epitaxial source/drain features 142 and 146 to subsequently formed source/drain contacts 176. The silicide layer 178 may be formed by depositing a metal source layer over epitaxial source/drain features 142 and 146 and performing a rapid thermal annealing process. During the rapid anneal process, a portion of the metal source layer over the epitaxial source/drain features 142 and 146 reacts with the silicon in the epitaxial source/draini features 142 and 146 to form a silicide layer 178. Next, the unreacted portion of the metal source layer is removed. In some embodiments, silicide layer 178 is made of metal or metal alloy silicide, and the metal includes noble metals, refractory metals, rare earth metals, alloys thereof, or combinations thereof. Next, conductive material is formed in the contact openings to form the source/drain contacts 176. The conductive material may be made of materials including one or more of Ru, Mo, Co, Ni, W, Ti, Ta, Cu, Al, TiN, and TaN. Although not shown, prior to forming the source/drain contacts 176, a barrier layer (e.g., TiN, TaN, or the like) may be formed on the sidewalls of the contact openings. Next, a planarization process such as chemical mechanical polishing is performed to remove excess deposited contact material and expose the top surface of the source/drain contacts 176.

In FIG. 14, after the source/drain contacts 176 are formed, a contact opening 177 is formed to expose the uppermost gate electrode layer 172. The contact opening 177 penetrates the first interlayer dielectric layer 164, the contact etch stop layer 162, the first protective layer 110 and the gate dielectric layer 170 until the top surface of the uppermost gate electrode layer 172 is exposed. In some embodiments, the work function metal layer 171 and/or the filling metal 173 used in the gate electrode layer 172 may include metal, metal alloy, or metal silicide. Since the thickness of the filling metal 173 (e.g., TiN) inside the gate electrode layer 172 is relatively increased (i.e., D1>D2), the filling metal 173 will not be completely eliminated due to excessive etching. Therefore, the thicker filling metal 173 can still cover the work function metal layer 171 (e.g., N-type metal) to prevent the work function metal layer 171 from being oxidized.

The work function metal layer 171 may include a work function metal to provide an appropriate work function for the high dielectric constant/metal gate structure 174. For n-type GAA FETs, the work function metal layer 171 may include one or more n-type work function metals (N-type metals). The n-type work function metal may exemplarily include, but is not limited to, titanium aluminide (TiAl), titanium aluminum nitride (TiAlN), tantalum carbonitride (TaCN), hafnium (Hf), zirconium (Zr), titanium (Ti), tantalum (Ta), aluminum (Al), metal carbides (such as hafnium carbide (HfC), zirconium carbide (ZrC), titanium carbide (TiC), aluminum carbide (AlC), aluminides, and/or other appropriate material. On the other hand, for a p-type GAA FET, the work function metal layer 171 may include one or more p-type work function metals (P-type metals). P-type work function metals may illustratively include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other appropriate materials.

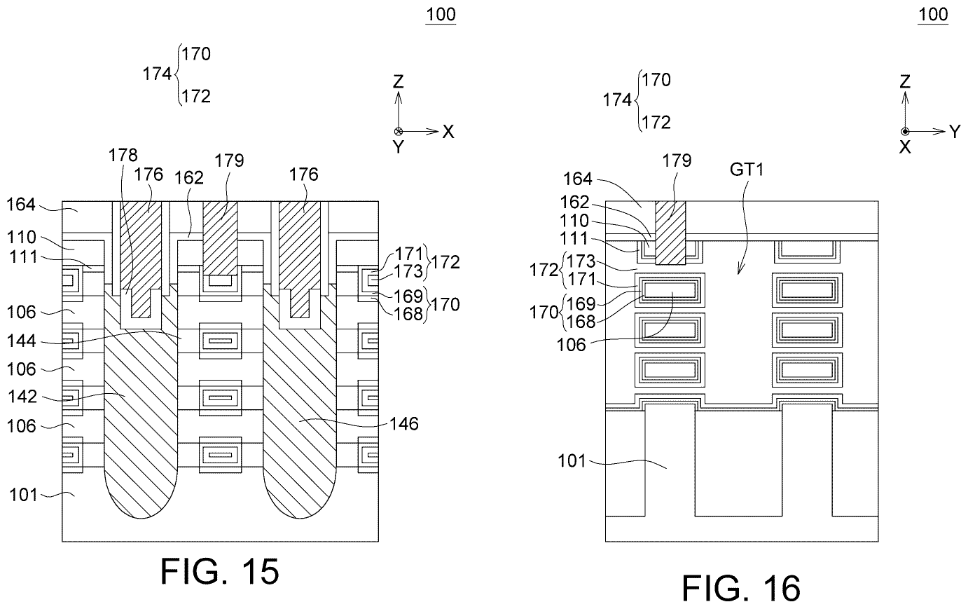

In FIG. 15, the gate contact 179 is formed in the contact opening 177 and is electrically connected to the uppermost gate electrode layer 172. In some embodiments, contact opening 177 is formed using suitable photolithography and etching techniques, and conductive material is deposited in contact opening 177 to form the gate contact 179. The conductive material may be made of materials including one or more of Ru, Mo, Co, Ni, W, Ti, Ta, Cu, Al, TiN, and TaN. Although not shown, a barrier layer (e.g., TiN, TaN, or the like) may be formed on sidewalls of the contact opening 177 before forming the gate contact 179. Next, a planarization process such as chemical mechanical polishing is performed to remove excess deposited contact material and expose the top surface of gate contact 179.

Referring to FIG. 16, a schematic cross-sectional view of the semiconductor device 100 in FIG. 15 on the Y-Z plane is shown. The gate structure 174 includes a gate dielectric layer 170 formed around the first semiconductor layers 106 (nanosheets), a work function metal layer 171 formed around the gate dielectric layer 170, and a filling metal 173 formed around the work function metal layer 171 and filling in the gate trenches GT1 in the Y-axis direction. Formation of gate structure 174 may include deposition of various gate materials, one or more dielectric layers, and one or more CMP processes to remove excess gate material. As shown in the cross-sectional view of FIG. 16, which is taken along the longitudinal axis of the gate structure 174, the gate structure 174 surrounds each of the first semiconductor layers 106 (nanosheets) and is therefore called the gate of GAA FET.

Reduction of the gate length and gate dielectric thickness in CMOS transistors for higher performance and circuit density aggravates problems such as high gate resistance. To alleviate these problems in nanosheet transistors, metal gate materials are introduced. The metal gate material (i.e., the gate electrode layer 172) not only eliminates the gate depletion and dopant penetration problems but also greatly reduces the gate sheet resistance. In some embodiments, due to the use of double-layered first and second protective layers 110 and 111, the thickness of each channel layer (i.e., the first semiconductor layer 106) can be kept consistent, so that each channel layer has a smaller drain induced barrier lowering (DIBL) to reduce the short channel effect.

It should be understood that the semiconductor device 100 may undergo further complementary metal oxide semiconductor (CMOS) processes and/or back-end-of-line (BEOL) processes to form various features, such as transistors, contacts/vias, interconnect metal layers, dielectric layers, passivation layers, etc. The semiconductor device 100 may also include backside source/drain contacts on the backside of substrate 101 such that the sources or drains of epitaxial source/drain features 142 and 146 are connected to the backside power rail (for example, positive voltage VDD or negative voltage VSS) via the backside source/drain contacts.

The present disclosure is directed to a semiconductor device and a manufacturing method thereof. The semiconductor device includes an improved protective layer to create a large space for gate filling metal (such as TiN). Since the thickness of the filling metal inside the gate electrode layer is relatively increased (i.e., D1>D2), the filling metal will not be completely eliminated due to excessive etching. Therefore, the thicker filling metal can still cover the work function metal layer (e.g., N-type metal) to prevent the work function metal layer from being oxidized.

According to some embodiments of the present disclosure, a method for manufacturing a semiconductor device is provided, including the following steps. A fin structure and at least one protective layer are formed on a substrate. The fin structure includes a plurality of first semiconductor layers and a plurality of second semiconductor layers that are alternately stacked. The protective layer covers a uppermost second semiconductor layer. A sacrificial gate structure is formed over a portion of the fin structure. The first semiconductor layers, the second semiconductor layers and the protective layer not covered by the sacrificial gate structure in a source/drain region of the fin structure are removed. The second semiconductor layers are removed to form at least one cavity between the first semiconductor layers. A sacrificial dielectric layer is formed between the first semiconductor layers. Edge portions and bottom portions of the sacrificial dielectric layer are removed. A plurality of dielectric spacers are formed on sidewalls of the sacrificial dielectric layer and between the first semiconductor layers. The sacrificial dielectric layer located under the protective layer and between the first semiconductor layers is removed to form a first cavity and a second cavity. The protective layer exposed in the first cavity is removed so that a height of the first cavity is greater than a height of the second cavity. A first gate structure and a second gate structure are formed in the first cavity and the second cavity respectively.

According to some embodiments of the present disclosure, a method for manufacturing a semiconductor device is provided, including the following steps. A first protective layer and a second protective layer are formed on top of a stack of a plurality of first semiconductor layers and a plurality of second semiconductor layers alternately disposed. The second semiconductor layers are removed to form at least one cavity between the first semiconductor layers. A sacrificial dielectric layer and a plurality of dielectric spacers are formed between the first semiconductor layers. The sacrificial dielectric layer located under the second protective layer is removed to form a first cavity. The sacrificial dielectric layer between the first semiconductor layers is removed to form a second cavity. The second protective layer exposed in the first cavity is removed so that the height of the first cavity is greater than the height of the second cavity.

According to some embodiments of the present disclosure, a semiconductor device includes a first protective layer, a second protective layer, two or more semiconductor layers, a first dielectric spacer, at least a second dielectric spacer, a first gate structure and at least a second gate structure. The first protective layer and the second protective layer are disposed above two or more semiconductor layers. The first dielectric spacer is located between the second protective layer and the uppermost semiconductor layer and around the first gate structure. At least a second dielectric spacer is located between the two or more semiconductor layers and around the second gate structure. The first gate structure is located between the first protective layer and the uppermost semiconductor layer, and the first gate structure has a first height. The second gate structure is located between the two or more semiconductor layers, and the second gate structure has a second height. The first height is greater than the second height.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a fin structure and at least one protective layer on a substrate, wherein the fin structure includes a plurality of first semiconductor layers and a plurality of second semiconductor layers that are alternately stacked, and the protective layer covers a uppermost second semiconductor layer of the second semiconductor layers;
forming a sacrificial gate structure over a portion of the fin structure;
removing the first semiconductor layers, the second semiconductor layers and the protective layer not covered by the sacrificial gate structure in a source/drain region of the fin structure;
removing the second semiconductor layers to form at least one cavity between the first semiconductor layers;
forming a sacrificial dielectric layer between the first semiconductor layers;
removing edge portions and a bottom portion of the sacrificial dielectric layer;
forming a plurality of dielectric spacers on sidewalls of the sacrificial dielectric layer and between the first semiconductor layers;
removing the sacrificial dielectric layer located under the protective layer and between the first semiconductor layers to form a first cavity and at least a second cavity;
removing the protective layer exposed in the first cavity so that a height of the first cavity is greater than a height of the second cavity;
forming a first gate structure in the first cavity; and
forming a second gate structure in the second cavity.

2. The method of claim 1, wherein the protective layer comprises a first protective layer and a second protective layer and each of the first and second protective layers comprises a material of silicon nitride (SiN), silicon oxynitride (SiON), silicon nitride carbide (SiCN), silicon oxycarbide (SiCO), silicon oxycarbonitride (SiOCN) or a combination thereof.

3. The method of claim 2, wherein a carbon content in the protective layer is between 0 to 6 atomic percent.

4. The method of claim 1, wherein a thickness of the protective layer is between 0.1 nm to 5 nm.

5. The method of claim 1, wherein the first gate structure has a first gate electrode layer, the second gate structure has a second gate electrode layer, and the first gate electrode layer has a thickness greater than a thickness of the second gate electrode layer.

6. The method of claim 5, further comprising:
forming a contact opening to expose the first gate electrode layer; and
forming a gate contact in the contact opening to electrically connect to the first gate electrode layer.

7. The method of claim 5, wherein the first gate electrode layer comprises a work function metal layer and a filling metal formed on the work function metal layer.

8. A method for manufacturing a semiconductor device, comprising:
forming a first protective layer and a second protective layer on top of a stack of a plurality of first semiconductor layers and a plurality of second semiconductor layers alternately disposed;
removing the second semiconductor layers to form at least one cavity between the first semiconductor layers;
forming a sacrificial dielectric layer and a plurality of dielectric spacers between the first semiconductor layers;
removing the sacrificial dielectric layer located under the second protective layer to form a first cavity;
removing the sacrificial dielectric layer between the first semiconductor layers to form a second cavity; and
removing the second protective layer exposed in the first cavity so that a height of the first cavity is greater than a height of the second cavity.

9. The method of claim 8, wherein each of the first and second protective layers comprises a material of silicon nitride (SiN), silicon oxynitride (SiON), silicon nitride carbide (SiCN), silicon oxycarbide (SiCO), silicon oxycarbonitride (SiOCN) or a combination thereof.

10. The method of claim 9, wherein a carbon content in the second protective layer is between 0 to 6 atomic percent.

11. The method of claim 9, wherein a thickness of the second protective layer is between 0.1 nm to 5 nm.

12. The method of claim 8, further comprising;
forming a first gate structure in the first cavity; and
forming a second gate structure in the second cavity;
wherein the first gate structure has a first gate electrode layer, the second gate structure has a second gate electrode layer, and the first gate electrode layer has a thickness greater than a thickness of the second gate electrode layer.

13. The method of claim 12, further comprising:
forming a contact opening to expose the first gate electrode layer; and
forming a gate contact in the contact opening to electrically connect to the first gate electrode layer.

14. The method of claim 12, wherein the first gate electrode layer comprises a work function metal layer and a filling metal formed on the work function metal layer.

15. A semiconductor device, comprising:
a first protective layer;
a second protective layer;
two or more semiconductor layers, wherein the first protective layer and the second protective layer are disposed above the two or more semiconductor layers;
a first dielectric spacer located between the second protective layer and a uppermost semiconductor layer of the two or more semiconductor layers;
at least a second dielectric spacer located between the two or more semiconductor layers;
a first gate structure surrounded by the first dielectric spacer; and
at least a second gate structure surrounded by the second dielectric spacer, wherein the first gate structure has a first height, the second gate structure has a second height, and the first height is greater than the second height.

16. The semiconductor device of claim 15, wherein each of the first and second protective layers comprises a material of silicon nitride (SiN), silicon oxynitride (SiON), silicon nitride carbide (SiCN), silicon oxycarbide (SiCO), silicon oxycarbonitride (SiOCN) or a combination thereof.

17. The semiconductor device of claim 16, wherein a carbon content in the second protective layer is between 0 to 6 atomic percent.

18. The semiconductor device of claim 16, wherein a thickness of the second protective layer is between 0.1 nm to 5 nm.

19. The semiconductor device of claim 15, wherein the first gate structure has a first gate electrode layer, the second gate structure has a second gate electrode layer, and the first gate electrode layer has a thickness greater than a thickness of the second gate electrode layer.

20. The semiconductor device of claim 19, further comprising:
a gate contact electrically connected to the first gate electrode layer, the first gate electrode layer comprises a work function metal layer and a filling metal formed on the work function metal layer.
